(19) United States
(12) Patent Application Publication
(10) Pub. No.: US 2008/0296750 A1
(43) Pub. Date: Dec. 4, 2008

(54) SEMICONDUCTOR DEVICE

(75) Inventor: Taibo NAKAZAWA, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/130,228

(22) Filed: May 30, 2008

(30) Foreign Application Priority Data
May 30, 2007 (JP) 2007-143877

(51) Int. Cl. H01L 23/48; H01L 31/00

(52) U.S. Cl. 257/690; 136/259; 257/E23.061

(57) ABSTRACT

A semiconductor device comprises a semiconductor chip having a photoelectric conversion function and conductor connecting with the semiconductor chip electrically. The semiconductor chip is sealed by resin. The resin comprises a first sealing resin, second sealing resin and third sealing resin. The second sealing resin has transparency for optical signal to the semiconductor chip and seals one side of the conductor. The third sealing resin seals the other side of the conductor and has a linear thermal expansion coefficient and thickness which may restrain at least a part of flexion of the conductor caused by the linear thermal expansion of the second sealing resin. The first sealing resin seals at least a part of the conductor, is sandwiched between the second sealing resin and the third sealing resin, and has a linear thermal expansion coefficient which may restrain at least a part of the linear thermal expansion of the second sealing resin.

### REFERENCE TO RELATED APPLICATION

This application is based upon and claims the benefit of the priority of Japanese patent application No. 2007-143877, filed on May 30, 2007, the disclosure of which is incorporated herein in its entirety by reference thereto.

### TECHNICAL FIELD

The prevent invention relates to a semiconductor device and, in particular, a semiconductor device having a photoelectric conversion function.

### BACKGROUND

In a semiconductor device, components such as a semiconductor chip and wiring are usually sealed by a resin to protect from the outer environment. As the resin for sealing, a resin including filler (glass pieces granulated finely, for example) is used usually. However, much filler in the resin for sealing deprives the transparency of the resin. For the resin sealing of the semiconductor chip having a photoelectric conversion function, a transparent resin for sealing without the filler is used in order to communicate without scattering the light between the inside and the outside of the semiconductor device.

In an optical module disclosed Patent Document 1, for example, an optical device and a print circuit board (may be termed as “print board” herein) are sealed separately, and the optical device is sealed with a transparent resin. In the resin sealing of the print board, in order to prevent a crack caused by the difference in heat expansion between the print board (alumina, for example) and the sealing resin (may be termed herein as “molding resin”), the print board is mounted on one side of a lead frame, both sides of the lead frame being sealed with the resin so as that the difference between the thickness of the molding resin from the top surface of the print board on the one side of the lead frame and the thickness of the molding resin on the other side is smaller than the thickness of the print board. This prevents the generation and concentration of the excess stress on both sides of the lead frame on which the print board is mounted.

### [Patent Document 1]

JP Patent Kokai Publication No. JP-P2000-243981A

### SUMMARY OF THE DISCLOSURE

The entire disclosure of Patent Document 1 is incorporated herein by reference thereto. The following analysis on the related art is given by the present invention.

A transparent resin for sealing, i.e. a resin without filler (or a resin not including much filler) has a linear expansion coefficient (thermal expansion coefficient), i.e. linear thermal expansion, larger than a resin including the filler and other components (a lead frame, a semiconductor chip and a bonding wire, for example) in the semiconductor device. The linear thermal expansion coefficient of each component is shown in Table 1. In Table 1, “a transparent sealing resin” means a resin without filler, and “a sealing resin including filler” means a resin whose content of the filler is 70 wt % to 90 wt %.

TABLE 1

| | Linear Thermal Expansion |
|---|---|
| Component | Coefficient (ppm/° C.) |
| Transparent Sealing Resin | 70 (Representative Value) |
| (Epoxy Resin) | [Temperature Lower than Glass |
| | Transition Temperature] |
| Transparent Sealing Resin | 170 (Representative Value) |
| (Epoxy Resin) | [Temperature Higher than Glass |
| | Transition Temperature] |
| Sealing Resin Including Filler | 10 (Representative Value) |
| (Epoxy Resin - Glass Particles) | [Temperature Lower than Glass |
| | Transition Temperature] |
| Sealing Resin Including Filler | 40 (Representative Value) |
| (Epoxy Resin - Glass Particles) | [Temperature Higher than Glass |
| | Transition Temperature] |
| Semiconductor Chip | 2 to 4 |
| (Si) | |
| Lead Frame (Conductor) | 5 to 20 |
| (FeNi Alloy) | [30° C. to 300° C.] |
| Bonding Wire | 14 to 16 |
| (Au) | |

Therefore, in the semiconductor device sealed with the transparent sealing resin, the heat in a reflow soldering process, for example, makes it easy to separate the interface between the transparent sealing resin without filler and the component such as the lead and to generate a crack in the sealing resin because of the difference in the linear thermal expansion coefficient. Thus there is much to be desired in the art.

According to a first aspect of the present invention, a semiconductor device comprises a semiconductor chip having a photoelectric conversion function and a conductor connecting with the semiconductor chip electrically, the semiconductor chip being sealed with resin. The resin comprises a first sealing resin, a second sealing resin and a third sealing resin. The second sealing resin has transparency for an optical signal to the semiconductor chip and seals one side of the conductor. The third sealing resin seals the other side of the conductor and has a linear thermal expansion coefficient and thickness which may restrain at least a part of flexion of the conductor caused by the linear thermal expansion of the second sealing resin. The first sealing resin seals at least a part of the conductor, is sandwiched between the second sealing resin and the third sealing resin, and has a linear thermal expansion coefficient which may restrain at least a part of the linear thermal expansion of the second sealing resin.

The meritorious effects of the present invention are summarized as follows.

According to the semiconductor device of the present invention, the first sealing resin restrains the linear thermal expansion of the second sealing resin to prevent the separation (pealing off) between the second sealing resin and other components. According to the semiconductor device of the present invention, the third sealing resin can prevent the deformation of the entire semiconductor device to avoid the generation of crack in the sealing resin, the breaking of the wiring and the separation of the sealing resin and other components. According to the present invention, therefore, heat reliance of the semiconductor device having the photoelectrical conversion function which is necessary to use a resin having transparency of a light signal (a transparent resin, preferably) can be enhanced.

### BRIEF DESCRIPTION OF THE DRAWINGS

FIG. 1 is a schematic perspective view of a semiconductor device according to a first exemplary embodiment of the present invention.

FIG. 2 is a schematic plan view of a semiconductor device according to a first exemplary embodiment of the present invention.

FIG. 3 is a schematic cross-sectional view along the III-III line in FIG. 2.

FIG. 4 is a schematic cross-sectional view along the IV-IV line in FIG. 2.

FIG. 5 is a schematic perspective view of a semiconductor device according to a second exemplary embodiment of the present invention.

FIG. 6 is a schematic plan view of a semiconductor device according to a second exemplary embodiment of the present invention.

FIG. 7 is a schematic cross-sectional view along the VII-VII line in FIG. 6.

FIG. 8 is a schematic cross-sectional view along the VIII-VIII line in FIG. 6.

### PREFERRED MODES OF THE INVENTION

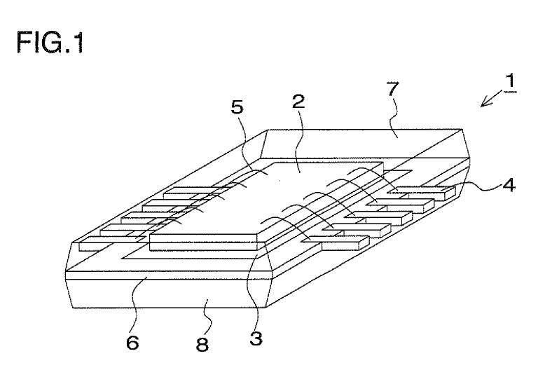

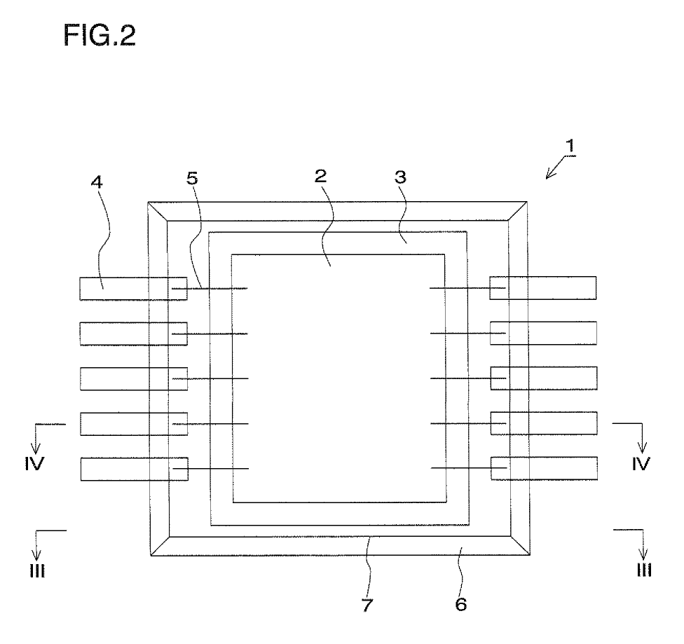

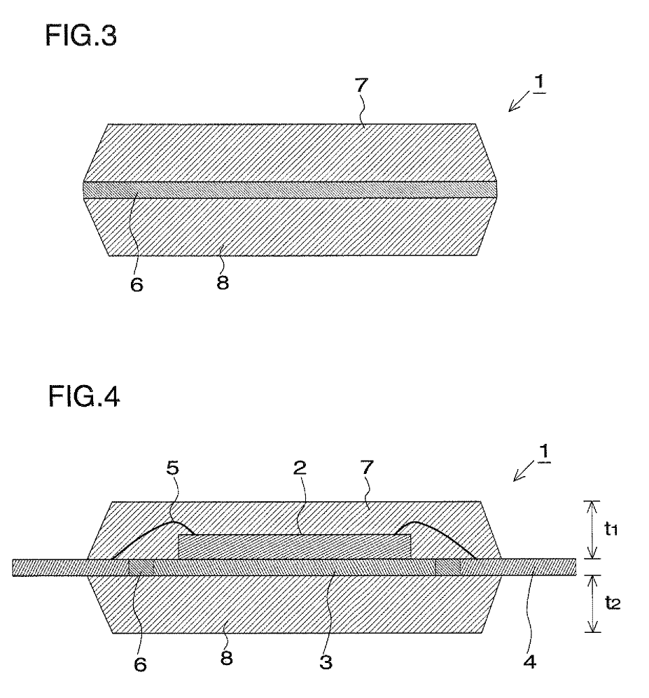

A semiconductor device according to a first exemplary embodiment of the present invention will be explained. FIG. 1 is a schematic perspective view of the semiconductor device according to the first exemplary embodiment of the present invention, and FIG. 2 is a schematic plan view of the semiconductor device. FIG. 3 is a schematic cross-sectional view along the III-III line in FIG. 2, and FIG. 4 is a schematic cross-sectional view along the IV-IV line in FIG. 2.

The semiconductor device 1 comprises a semiconductor chip 2 having a photoelectric conversion function, a conductor connecting with the semiconductor chip 2 electrically, and a sealing resin which seals them. The conductor includes, for instance, an island 3 on which the semiconductor chip 2 is mounted and which is electrically connected with the semiconductor ship 2 and leads 4 electrically connecting with the semiconductor chip 2 through bonding wires 5. In the semiconductor device, the semiconductor chip 2 and the components are sealed with three sealing resins, i.e. a first sealing resin 6, second sealing resin 7 and third sealing resin 8.

It is necessary that the second sealing resin 7 covering the semiconductor chip 2 has optical transparency enabling communication of a signal between the inside and the outside of the semiconductor device 1 because the semiconductor chip 2 is a photoelectrical conversion element. Therefore, the content of the filler in the second sealing resin 7 is 30 wt % or less preferably, and 0 wt % to 10 wt % more preferably, so as not to block the communication of the signal of the light. The linear thermal expansion coefficient (thermal expansion rate) of the epoxy resin including without filler is about 50 ppm/° C. or over in a range of temperature lower than the glass transition temperature of the resin and about 150 ppm/° C. or more in a range of temperature higher than the glass transition temperature of the resin, for example. A linear thermal expansion coefficient of a conductor (island 3 and lead 4) used generally is 5 ppm/° C. to 20 ppm/° C. (at 30° C. to 300° C.), and therefore the linear thermal expansion coefficient of the second sealing resin 7 is five times or more as much as the linear thermal expansion coefficient of the island 3 or lead 4 at the temperature higher than the glass transition temperature of the resin.

The first sealing resin 6 extends across the whole package of the semiconductor device 1 along the surface on which the semiconductor chip 2 is mounted, such as around the island 3, between the island 3 and the lead 4, and between the leads 4, and sandwiched between the second sealing resin 7 and the third sealing resin 8. In the first exemplary embodiment, the thickness of the first sealing resin 6 is equal to or less than the thickness of the island 3 and lead 4 (i.e. the thickness of the lead frame), and at least both surfaces of the island 3 or lead 4 are exposed from the first sealing resin 6. In the exemplary embodiment shown in FIG. 4, the island 3 and lead 4 are at the same level (height), and the thickness of the first sealing resin 6 is the same as the thickness of the island 3 and lead 4. The first sealing resin 6 is not in contact with a bottom surface of the semiconductor chip 2.

The first sealing resin 6 is selected from resins having a linear thermal expansion coefficient which may restrain at least a part of the thermal expansion of the second sealing resin 7. The linear thermal expansion coefficient of the first sealing resin 6 is made smaller than the linear thermal expansion coefficient of the second sealing resin 7 and third sealing resin 8. In order to make the linear thermal expansion coefficient of the first sealing resin 6 smaller than the linear thermal expansion coefficient of the second sealing resin 7 (and third sealing resin 8), it is preferred that the content of the filler in the first sealing resin 6 is made higher than the content of the filler in the second sealing resin 7 (and the third sealing resin 8). Accordingly, the content of the filler in the first sealing resin 6 is preferably 50 wt % or more and more preferably 70 wt % to 90 wt %. The linear thermal expansion coefficient of the epoxy resin whose content of the filler is 70 wt % to 90 wt % is about 30 ppm/° C. or less at the glass transition temperature or lower of the resin and about 100 ppm/° C. or less at the glass transition temperature or higher of the resin. Therefore, the linear thermal expansion coefficient of the first sealing resin 6 is preferably less than five times as much as the island 3 or lead 4 and more preferably four times or less.

The third sealing resin 8 is formed so as to sandwich the first sealing resin 6 with the second sealing rein 7. The third sealing resin 8 is formed on the back side of the surface on which the semiconductor chip 2 is mounted. The third sealing resin 8 is selected from resins having a linear thermal expansion coefficient and thickness which may restrain at least a part of flexion of the conductor such as the island 3 due to the thermal expansion of the second sealing resin 7.

The linear thermal expansion coefficient of the third sealing resin 8 is equal to or close to the linear thermal expansion coefficient of the second sealing resin 7 preferably, and about 50 ppm/° C. or more at the glass transition temperature or lower of the resin and about 150 ppm/° C. or more at the glass transition temperature or higher. Accordingly, it is preferred that the linear thermal expansion coefficient of the third sealing resin 8 is five times or more as much as the linear thermal expansion coefficient of the island 3 or lead 4 at the glass transition temperature of the resin or higher. In order to make the linear thermal expansion coefficient of the third sealing resin 8 equal to or close to the linear thermal expansion coefficient of the second sealing resin 7, the content of the filler in the third sealing resin 8 is equal to or close to the content of the filler in the second sealing resin 7 preferably. Accordingly, the content of the filler in the third sealing resin 8 is 30 wt % or less preferably and 0 wt % to 10 wt % more preferably. The third sealing resin 8 is made from the same material as the second sealing resin 7 further preferably.

It is preferred that the thickness t₁ of the second sealing resin 7 from the surface on which the semiconductor chip 2 is mounted and the thickness t₂ of the third sealing resin 8 from the back of the surface are close to each other as much as possible. It is preferred that one thickness of the thickness t₁ of the second sealing resin 7 and the thickness t₂ of the third sealing resin 8 is ±50% or less of the other thickness, for example.

In order to offset an influence of the thermal expansion at the second sealing resin 7 side by an influence of the thermal expansion at the third sealing resin 8 side more efficiently, a dummy element having a linear thermal expansion coefficient and/or size similar to of the semiconductor chip 2 may be provided. This enhances the symmetry between the second sealing resin 7 side and the third sealing resin 8 side to bring the degree of the deformation closer to each other in view of the linear thermal expansion coefficient and of the thickness of the sealing resin.

The same type of adhesive resin (epoxy resin, for example) is used for the first sealing resin 6 and second sealing resin 7 or the first sealing resin 6 and third sealing resin 8 preferably, and the adhesive resin for the first sealing resin 6, second sealing resin 7 and third sealing resin 8 is unified more preferably. This enhances the compatibility (adhesion) between the first sealing resin 6 and the second sealing resin 7 and between the first sealing resin 6 and the third sealing rein 8.

In the present invention, “the linear thermal expansion coefficient” of the sealing resin is calculated from “an average linear thermal expansion coefficient” measured in a range of from a glass transition temperature of resin to 300° C. based on JISK7197. In the present invention, “the linear thermal expansion coefficient” of the conductor is calculated from “an average linear thermal expansion coefficient” measured in a range of from a glass transition temperature of the resin to 300° C. based on JISZ2285.

Next, an action of the present invention will be explained. In the semiconductor device 1 of the present invention, the transparent second sealing resin 7 is in contact with the first sealing resin 6, and preferably the linear thermal expansion coefficient of the first sealing resin 6 is smaller than the linear thermal expansion coefficient of the second sealing resin 7. The compatibility (adhesion) between the second sealing resin 7 and the first sealing resin 6 is higher than the compatibility between the second sealing resin 7 and other components (the conductors 3, 4, semiconductor chip 2, for example). Therefore, even if the second sealing resin 7 is heat-expanded by heating the semiconductor device 1, the first sealing resin 6 can restrain the thermal expansion of the second sealing resin 7. According to the present invention, this can prevent the separation of the second sealing resin 7 and other components. The difference in the linear thermal expansion coefficient between the second sealing resin 7 and the first sealing resin 6 is smaller than the difference in the linear thermal expansion coefficient between the second sealing resin 7 and other components, and the compatibility between the second sealing resin 7 and the first sealing resin 6 is higher, so the separation between the second sealing resin 7 and the first sealing resin 6 may not occur. The difference in the linear thermal expansion coefficient between the first sealing resin 6 and other components is smaller than the difference in the linear thermal expansion coefficient between the second sealing resin 7 and the other components, so the separation of the first sealing resin 6 and the other components may be restrained The above effect is applied to between the third sealing resin 8 and the first sealing resin 6 and the other components.

In the semiconductor device 1 of the present invention, the third sealing resin 8 which is in contact with the first sealing resin 6 is formed at the opposite side of the second sealing resin 7, and preferably the linear thermal expansion coefficient of the third sealing resin 8 is equal to or close to the linear thermal expansion coefficient of the second sealing resin 7. Therefore, even if the second sealing resin 7 is thermally-expanded by heating the semiconductor device 1, the third sealing resin 8 is expanded likewise, so the force generating the flexion by the second sealing resin 7 in the semiconductor device is offset by the third sealing resin 8. According to the semiconductor device 1 of the present invention, this can prevent the deformation of the entire semiconductor device 1 and therefore avoid generation of cracks in the sealing resin, the breaking of the wiring, and the separation of the sealing resin and other components.

Next, an example of a process of manufacturing the semiconductor device 1 according to the first exemplary embodiment of the present invention will be explained. Before the semiconductor chip 2 is mounted on the lead frame, the periphery of the island 3 of the lead frame, the spaces between the island 3 and the leads 4 and the spaces between the leads 4 are sealed by the first sealing resin 6 by way of molding. Next, the semiconductor chip 2 is mounted on the island 3, and the pads in the semiconductor chip 2 are connected with the leads 4 through the bonding wires 5 electrically. Next, the lead frame and the first sealing resin 6 are sandwiched and sealed by the second sealing resin 7 and the third sealing resin 8 which are made from the same material to manufacture the package of the semiconductor device 1.

According to the first exemplary embodiment of the present invention, because of the adhesion and difference in the linear thermal expansion coefficient between the first sealing resin and the second sealing resin and third sealing resin, the first sealing resin can restrain the thermal expansion of the second sealing resin and third sealing resin. This can prevent the separation between the second sealing resin and third sealing resin and other components.

The force of deforming the semiconductor device is cancelled by forming the second sealing resin and third sealing resin so as to be symmetrical about the first sealing resin. This can prevent the generation of crack, the breaking of the wiring and the separation of the sealing resin and the other components.

In the above explanation, although an example that the semiconductor device is heated and that the sealing resin is heat-expanded thereby is explained, an example that the semiconductor device is cooled (a temperature cycle test for an accelerating environment test, for example) and the sealing resin contracts is similar.

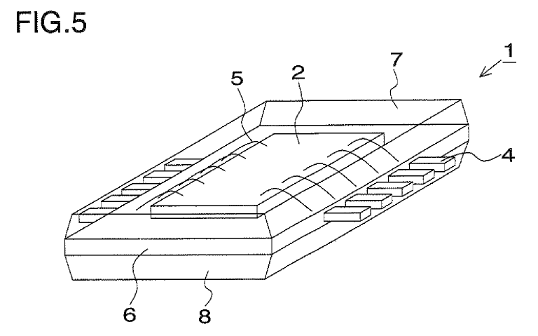

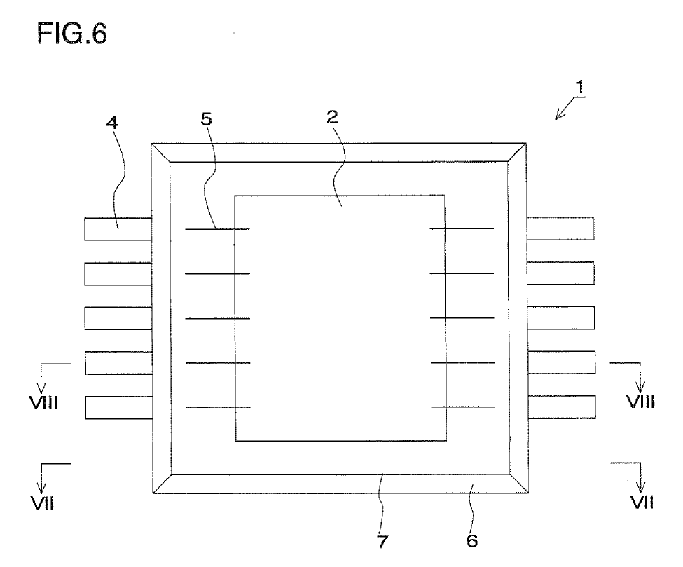

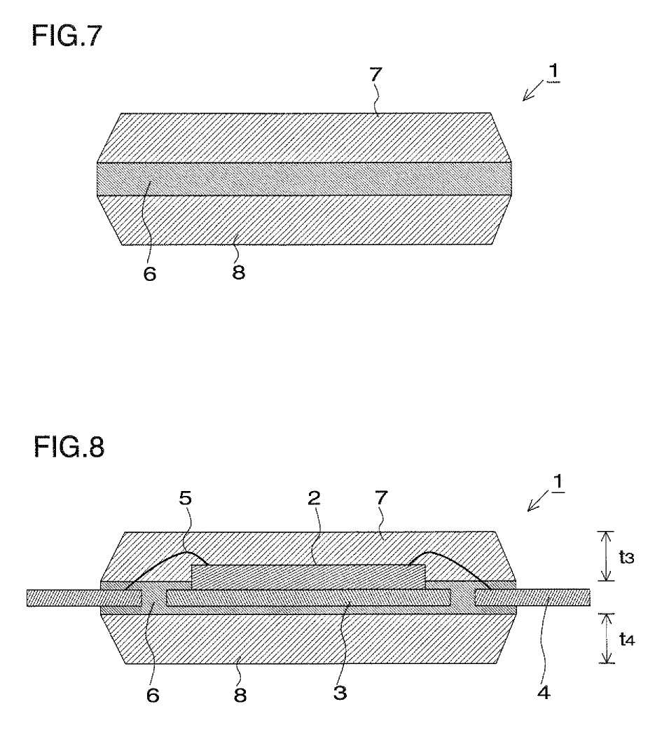

A semiconductor device according to a second exemplary embodiment of the present invention will be explained. FIG. 5 is a schematic perspective view of the semiconductor device according to the second exemplary embodiment of the present invention, and FIG. 6 is a schematic plan view of the semiconductor device. FIG. 7 is a schematic cross-sectional view along the VII-VII line in FIG. 6, and FIG. 8 is a schematic cross-sectional view along the VIII-VIII line in FIG. 6.

In the first exemplary embodiment, the thickness of the first sealing resin 6 is less than the thickness of the island 3 or lead 4 and at least the surface of the island 3 or lead 4 is exposed from the first sealing resin 6, whereas, in the second exemplary embodiment, the thickness of the first sealing resin 6 is greater than the thickness of the island 3 or lead 4 and the surface of the island 3 or lead in the package is not exposed from the first sealing resin 6. That is, the island 3 and leads 4 are sealed by the first sealing resin 6. Accordingly, in the first exemplary embodiment, the second sealing resin 7 or third sealing resin 8 is in contact with the island 3 or lead 4 directly, whereas, in the second exemplary embodiment, the second sealing resin 7 or third sealing resin 8 is not in contact with the island 3 or lead 4 directly. Except for the above, the second exemplary embodiment is likewise as the first exemplary embodiment.

The first sealing resin 6 covers and seals the top and back surfaces of the island 3 and leads 4 within the sealing resin. The upper limit of the thickness of the first sealing resin 6 is determined so as not to lose the photoelectric conversion function of the semiconductor chip 2, i.e. not to block the communication of signal between the inside and the outside of the semiconductor device 1. The first sealing resin 6 has low transparency, so if too thick, the communication of signal by the semiconductor chip 2 is blocked.

The thickness t3 of the second sealing resin 7 from the surface of the first sealing resin 6 at the semiconductor chip 2 side is preferably equal to or close to the thickness t4 of the third sealing resin 8 from the surface of the first sealing resin 6 at the back side. One thickness of the thickness t3 of the second sealing resin 7 and the thickness t4 of the third sealing resin 8 is preferably ±50% or less of the other thickness, for example.

Next, an example of a process of manufacturing the semiconductor device 1 according to the second exemplary embodiment of the present invention will be explained. First, a semiconductor chip 2 is mounted on the island 3, and the pads in the semiconductor chip 2 are connected with the leads 4 through the bonding wires 5 electrically. Next, the island 3 and a part of the leads 4 (inner lead parts) of the lead frame are covered and sealed with the first sealing resin 6. Next, the first sealing resin 6 is sandwiched and sealed with the second sealing resin 7 and the third sealing resin 8 which are made from the same material to manufacture the package of the semiconductor device 1.

According to the second exemplary embodiment, the island and leads which have the lower linear thermal expansion coefficient are not in contact with the second sealing resin and third sealing resin which have the larger linear thermal expansion coefficient directly and are in contact with the first sealing resin 6 which has the coefficient lower than the second sealing resin and third sealing resin. So, even if the sealing resin is heat-expanded, the separation between the island or lead and the sealing resin is hard to occur as compared with the first exemplary embodiment. Since the contact area between the second sealing resin and third sealing resin and the first sealing resin is greater than one in the first exemplary embodiment, the heat expansion of the second sealing resin and third sealing resin can be restrained more effectively and the separation between the second sealing resin and third sealing resin and the first sealing resin is hard to occur.

The explanation of the first exemplary embodiment is referred to for further explanation of the semiconductor device according to the second exemplary embodiment.

The present invention is suitable for a semiconductor device comprising a semiconductor chip having a photoelectric conversion function, and also may be applied to any type of a semiconductor device without limiting a function of the semiconductor chip.

Although the semiconductor device of the present invention is explained based on the first and second exemplary embodiments, the semiconductor device of the present invention may include any modification, change and improvement to the exemplary embodiment within the scope of the present invention and based on the technical idea of the present invention without being limited to the exemplary embodiment. Within the scope of the present invention, various combinations, displacements and selections of disclosed elements are available.

A further problem, object and exemplary embodiment of the present invention become clear from the entire disclosure of the present invention including claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a semiconductor chip having a photoelectric conversion function, and a conductor connecting with the semiconductor chip electrically, the semiconductor chip being sealed with resin; wherein
the resin comprises a first sealing resin, a second sealing resin and a third sealing resin;
the second sealing resin has transparency for an optical signal to the semiconductor chip and seals one side of the conductor;
the third sealing resin seals the other side of the conductor and has a linear thermal expansion coefficient and thickness which may restrain at least a part of flexion of the conductor caused by the linear thermal expansion of the second sealing resin; and
the first sealing resin seals at least a part of the conductor, is sandwiched between the second sealing resin and the third sealing resin, and has a linear thermal expansion coefficient which may restrain at least a part of the linear thermal expansion of the second sealing resin.

2. The semiconductor device according to claim 1, wherein
the third sealing resin has the linear thermal expansion coefficient of 150 ppm/° C. or more in a range from a glass transition temperature to 300° C.;
the first sealing resin has a linear thermal expansion coefficient of 100 ppm/° C. or more in a range from a glass transition temperature to 300° C.

3. The semiconductor device according to claim 2,
wherein the second sealing resin has a linear thermal expansion coefficient of 150 ppm/° C. or more in a range from a glass transition temperature to 300° C.

4. The semiconductor device according to claim 3,
wherein the second sealing resin and the third sealing resin are formed from the same material.

5. The semiconductor device according claim 1,
wherein one of the second sealing resin and third sealing resin has a thickness ranging from 50% to 150% as that of the other.

6. The semiconductor device according claim 1, wherein
the thickness of the first sealing resin is equal to or smaller than the thickness of the conductor; and
at least surfaces at both sides of the conductor are exposed out of the first sealing resin.

7. The semiconductor device according claim 1, wherein
the first sealing resin has a thickness equal to or greater than that of the conductor; and
surfaces at both sides of the conductor are not exposed out of the first sealing resin.
